(19) United States
(12) Patent Application Publication
(10) Pub. No.: US 2025/0012626 A1
(43) Pub. Date: Jan. 9, 2025

(54) LIGHT-EMITTING DEVICE WITH SENSING FUNCTION AND SENSING DEVICE

(71) Applicant: INDUSTRIAL TECHNOLOGY RESEARCH INSTITUTE, Hsinchu (TW)

(72) Inventors: Ming-Chieh Chou, Kaohsiung City (TW); Guang-Huei GU, Tainan City (TW); Yu-Lin WANG, Tainan City (TW)

(73) Assignee: INDUSTRIAL TECHNOLOGY RESEARCH INSTITUTE, Hsinchu (TW)

(21) Appl. No.: 18/422,477

(22) Filed: Jan. 25, 2024

(30) Foreign Application Priority Data
Jul. 4, 2023 (TW) 112124903

(51) Int. Cl. G01J 1/02; G01J 1/42; H01L 31/14; H05B 47/105

(52) U.S. Cl. CPC G01J 1/0271; G01J 1/4257; H01L 31/14; H05B 47/105

(57) ABSTRACT

A light-emitting device with a sensing function is provided. The light-emitting device includes a substrate, a first light-emitting-diode die, and a first photosensitive element. The first light-emitting-diode die is disposed on the substrate and includes a main light-emitting top surface and a side light-emitting surface surrounding the main light-emitting top surface. The first photosensitive element is disposed on the substrate and includes a photosensitive surface. The photosensitive surface is parallel to the main light-emitting top surface. A distance between the main light-emitting top surface and the substrate is greater than a distance between the photosensitive surface and the substrate distance.

### CROSS REFERENCE TO RELATED APPLICATIONS

The present application is based on, and claims priority from, Taiwan (International) Application Serial Number 112124903, filed Jul. 4, 2023, the disclosure of which is hereby incorporated by reference herein in its entirety.

### TECHNICAL FIELD

The disclosure relates to a light-emitting device, in particular to a light-emitting device with a sensing function.

### BACKGROUND

In order to stabilize the brightness of a light-emitting diode, a conventional control circuit may use an additional photo detector installed outside the light-emitting diode to detect the brightness of the light-emitting diode. The control circuit adjusts the brightness of the light-emitting diode according to the detection result provided by the photo detector. However, the photo detector are additional element installed separately, so it is difficult to control the distance, relative position or environment between the photo detector and the light-emitting diode precisely. Therefore, the brightness of the light-emitting diode will not be able to be tracing correctly that the control or calibration procedure on brightness of a light-emitting diode would become weaken then.

### SUMMARY

The disclosure provides an exemplary embodiment of a light-emitting device with a sensing function. The light-emitting device comprises a substrate, a first light-emitting-diode die, and a first photosensitive element. The first light-emitting-diode die is disposed on the substrate and comprises a main light-emitting top surface and a side light-emitting surface surrounding the main light-emitting top surface. The first photosensitive element is disposed on the substrate and comprises a photosensitive surface. The photosensitive surface is parallel to the main light-emitting top surface. A distance between the main light-emitting top surface and the substrate is greater than a distance between the photosensitive surface and the substrate distance.

The disclosure provides an exemplary embodiment of a sensing device. The sensing device comprises a light-emitting device. The light-emitting device comprises a substrate, a light-emitting-diode die, and a first photosensitive element. The light-emitting-diode die is disposed on the substrate and comprises a main light-emitting top surface and a side light-emitting surface. The side light-emitting surface surrounds the main light-emitting top surface. The first photosensitive element is disposed on the substrate and comprises a photosensitive surface. The first photosensitive element receives an effective light through the photosensitive surface to generate a first detection result. The photosensitive surface is parallel to the main light-emitting top surface. A distance between the main light-emitting top surface and the substrate is greater than a distance between the photosensitive surface and the substrate. The sensing device further comprises a first analog front-end circuit, a second photosensitive element, a second analog front-end circuit, a micro control circuit, and a driving circuit. The first analog front-end circuit is coupled to the light-emitting device to receive the first detection result. The first analog front-end circuit processes the first detection result to generate a first output signal. The second photosensitive element senses a light beam emitted by the light-emitting-diode die to generate a second detection result. The second analog front-end circuit is coupled to the first photosensitive element to receive the second detection result. The second analog front-end circuit processes the second detection result to generate a second output signal. The micro control circuit is coupled to the first analog front-end circuit and the second analog front-end circuit to receive the first output signal and the second output signal respectively. The micro control circuit generates a control signal according to the first output signal and the second output signal. The driving circuit is coupled to the micro control circuit to receive the control signal. The driving circuit controls luminous intensity of the light-emitting-diode die according to the control signal.

### BRIEF DESCRIPTION OF THE DRAWINGS

FIG. 1A is a schematic diagram showing an exemplary embodiment of a light-emitting device of the disclosure;

FIG. 1B is a top view of one exemplary embodiment of a light-emitting device of the disclosure;

FIG. 1C is a top view of another exemplary embodiment of a light-emitting device of the disclosure;

FIG. 1D is a top view of another exemplary embodiment of a light-emitting device of the disclosure;

FIG. 2 is a schematic diagram showing an exemplary embodiment of positions of a light-emitting-diode die and a photo detector of the disclosure;

FIG. 3 is a schematic diagram showing an exemplary embodiment of a sensing device of the disclosure; and

FIG. 4 is a schematic diagram showing an exemplary embodiment of a photo detector of the disclosure.

### DETAILED DESCRIPTION

The disclosure will be described with respect to particular embodiments and with reference to certain drawings, but the disclosure is not limited thereto and is only limited by the claims. The drawings described are only schematic and are non-limiting. In the drawings, the size of some of the elements may be exaggerated for illustrative purposes and not drawn to scale. The dimensions and the relative dimensions do not correspond to actual dimensions in the practice of the disclosure.

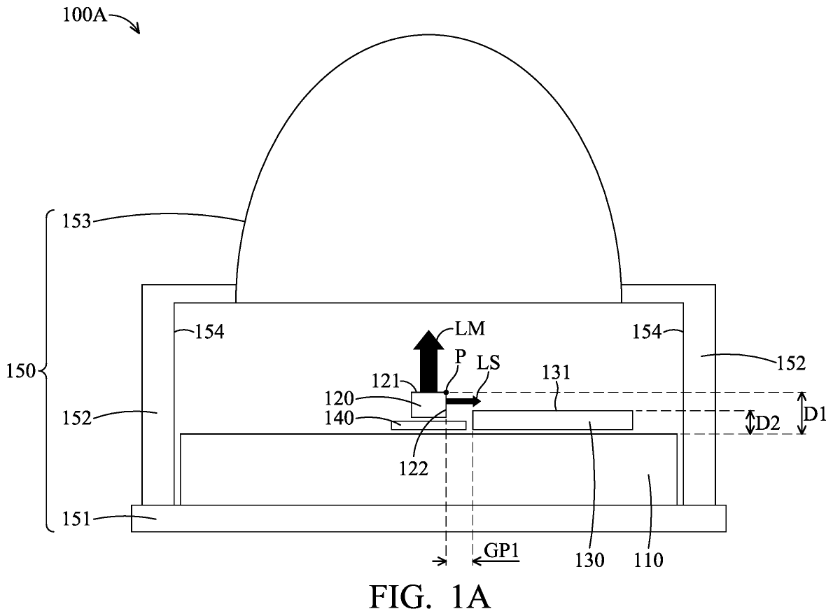

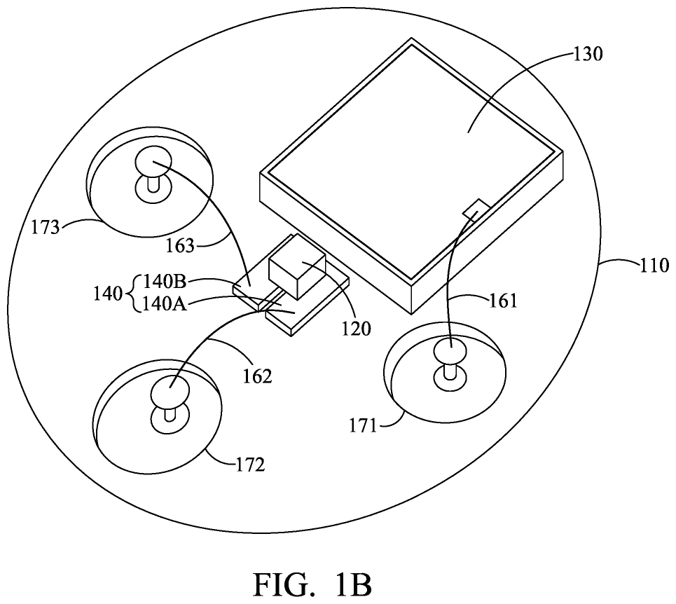

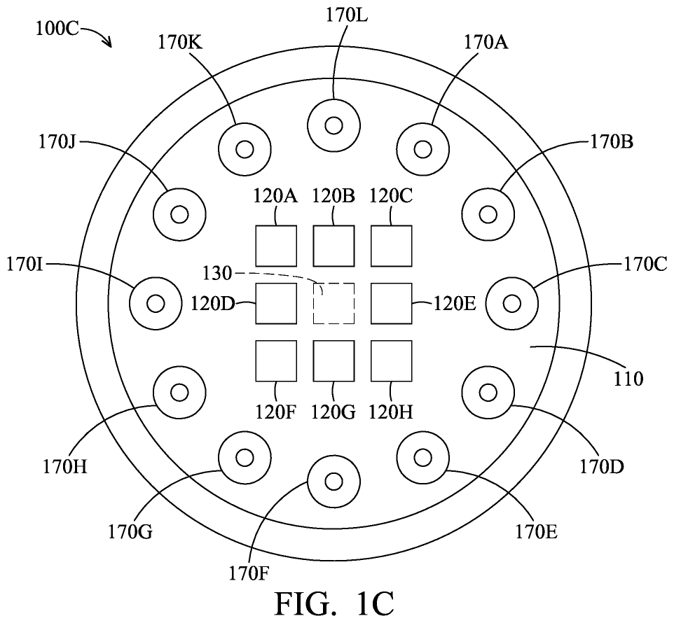

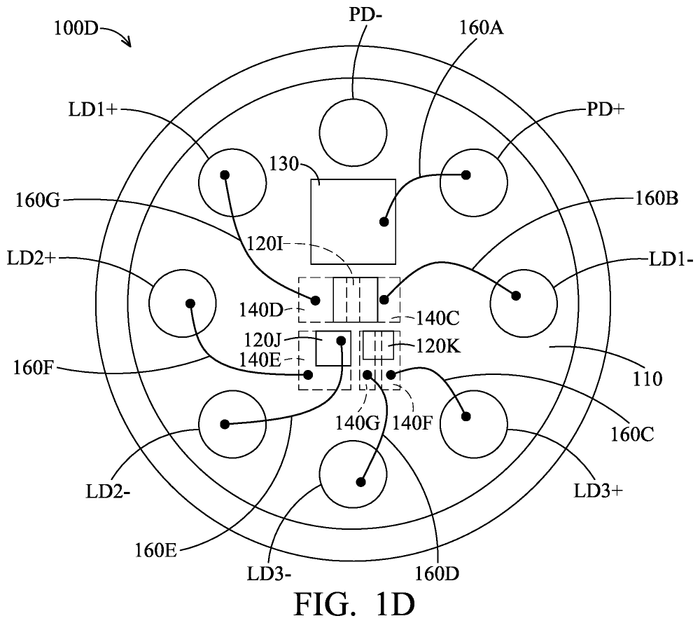

FIG. 1A is a schematic diagram showing an exemplary embodiment of a light-emitting device of the disclosure. As shown in FIG. 1, the light-emitting device 100A comprises a substrate 110, a light-emitting-diode (LED) die 120, and a photosensitive element 130. In the embodiment, the light-emitting device 100A is provided with not only a light-emitting function, but also a light sensing function. The disclosure does intend to limit the type of the substrate 110. In some embodiments, the substrate 110 is implemented by a conductive substrate or an insulation substrate.

The light-emitting-diode die 120 is disposed on the substrate 110 and comprises a main light-emitting top surface 121 and a side light-emitting surface 122. The side light-emitting surface 122 surrounds the main light-emitting top surface 121. In an exemplary embodiment, the main light-emitting top surface 121 is perpendicular to the side light-emitting surface 122. In the embodiment, the light-emitting-diode die 120 emits a main light beam LM through the main light-emitting top surface 121 and emits a side light beam LS through the side light-emitting surface 122. The traveling direction of the main light beam LM is perpendicular to the traveling direction of the side light beams LS.

The photosensitive element 130 is disposed on the substrate 110 and comprises a photosensitive surface 131. The photosensitive surface 131 is parallel to the main light-emitting top surface 121. In an exemplary embodiment, the photosensitive surface 131 is perpendicular to the side light-emitting surface 122. The photosensitive surface 131 mainly detects the brightness of the side light beam LS. In an exemplary embodiment, the distance D1 between the main light-emitting top surface 121 and the substrate 110 is greater than the distance D2 between the photosensitive surface 131 and the substrate 110. In another exemplary embodiment, the photosensitive surface 131 is lower than the highest point P of the side light-emitting surface 122. Therefore, the photosensitive surface 131 can receive most of the side light beams LS. In the embodiment, the side light beam LS directly enters the photosensitive surface 131. Since the photosensitive element 130 is adjacent to the light-emitting-diode die 120 and is integrated with the light-emitting-diode die 120 on the same substrate 110, the detection result of the photosensitive element 130 will not be affected by external noise light or media, which greatly improving the accuracy of the photosensitive element 130. In an exemplary embodiment, the substrate 110, the light-emitting-diode die 120, and the photosensitive element 131 are packaged together.

In FIG. 1A, there is a gap GP1 between the side light-emitting surface 122 and the photosensitive element 130. The side light beam LS emitted from the side light-emitting surface 122 directly passes through the gap GP1 and enters the photosensitive surface 131. In the embodiment, the photosensitive surface 131 mainly receives light passing through the gap GP1.

In some embodiments, the light-emitting device 100A further comprises a substrate 140. The substrate 140 is disposed between the light-emitting-diode die 120 and the substrate 110. The disclosure does not intend to limit the type of the substrate 140. The substrate 140 can be implemented as a supporting substrate for raising the light-emitting-diode die 120 so that the distance D1 between the main light-emitting top surface 121 and the substrate 110 is greater than the distance D2 between the photosensitive surface 131 and the substrate 110. In an exemplary embodiment, the highest point P of the side light-emitting surface 122 is higher than the photosensitive surface 131. In another exemplary embodiment, the substrate 140 is implemented by a conductive substrate for electrically connecting the light-emitting-diode die 120. In this embodiment, the substrate 140 can also raise the light-emitting-diode die 120.

In an exemplary embodiment, the light-emitting-diode die 120 comprises a positive terminal (not shown) and a negative terminal (not shown). The positive terminal and the negative terminal may be disposed on the same surface or different surfaces of the light-emitting-diode die 120. For example, when the positive terminal or the negative terminal is disposed on the back surface of the light-emitting-diode die 120 (relative to the main light-emitting top surface 121 of the light-emitting-diode die 120), the substrate 140 is electrically connected to the positive terminal or the negative terminal on the back surface of the light-emitting-diode die 120 (that is, the surface facing the substrate 110). When both the positive terminal and the negative terminal of the light-emitting-diode die 120 face the substrate 110, the substrate 140 is electrically connected to the positive terminal and the negative terminal of the light-emitting-diode die 120. In an exemplary embodiment, the substrate 140 may comprise a first conductive region and a second conductive region. The first conductive region is electrically connected to the positive terminal of the light-emitting-diode die 120. The second conductive region is electrically connected to the negative terminal of the light-emitting-diode die 120.

In some embodiments, the light-emitting device 100A further comprises a protection housing 150. The protection housing 150 protects the light-emitting-diode die 120 and the photosensitive element 130. The protection housing 150 at least comprises protection plates 151 and 152. The protection plate 151 is disposed under the substrate 110 for carrying the substrate 110. The protection plate 152 surrounds the light-emitting-diode die 120 and the photosensitive element 130. The disclosure does not intend to limit the material of the protection plate 152. In an exemplary embodiment, the material of the protection plate 152 comprises metal (such as iron) or electroplated metal (such as nickel, aluminum). In this embodiment, when the light-emitting-diode die 120 emits light, the photosensitive element 130 can receive the direct light (such as the side light beam LS) from the light-emitting-diode die 120 and the reflected light from the protection plate 152. In another exemplary embodiment, the protection plate 152 comprises a side surface 154 facing the light-emitting-diode die 120 and the photosensitive element 130. The side surface 154 is coated with light-absorbing material. In this embodiment, when the light-emitting-diode die 120 emits light, the photosensitive element 130 receives only the direct light (such as side light beam LS) but does not receive reflected light.

In some embodiments, the protection housing 150 further comprises a protection lid 153. The protection lid 153 is disposed above the light-emitting-diode die 120 and the photosensitive element 130 and covers the light-emitting-diode die 120 and the photosensitive element 130. The protection lid 153 is provided with a semicircular structure. The protection lid 153 could be made of a transparent material for allowing the main light beam LM to pass through. In an exemplary embodiment, the protection lid 153 is implemented by a transparent lens.

FIG. 1B is a top view of one exemplary embodiment of the light-emitting device 100A of the disclosure. It is assumed that the positive terminal and the negative terminal of the light-emitting-diode die 120 face the substrate 110. In this embodiment, the substrate 140 comprises electrically-connected substrates 140A and 140B. The substrate 110 is electrically insulated from the electrically-connected substrates 140A and 140B, that is, there is non-conduction between the electrically-connected substrates 140A and 140B and the substrate 110. The electrically-connected substrate 140A is electrically connected to the positive terminal of the light-emitting-diode die 120 and further electrically connected to a terminal 172 through a conductive wire 162. The electrically-connected substrate 140B is electrically connected to the negative terminal of the light-emitting-diode die 120 and further electrically connected to a terminal 173 through a conductive wire 163. The positive terminal of the photosensitive element 130 is electrically connected to the terminal 171 through the conductive wire 161. The negative terminal of the photosensitive element 130 is disposed on the bottom surface of the photosensitive element 130 and electrically connected to the substrate 110 through a conductive material (such as conductive glue) between the photosensitive element 130 and the substrate 110. In this case, the substrate 110 is a conductive substrate (comprising metal, such as copper, iron, etc.), and the negative terminal of the photosensitive element 130 is electrically connected to the outside through the substrate 110. In some embodiments, the light-emitting-diode die 120 can be driven after an appropriate current is provided to the terminals 172-173, and the photosensitive element 130 can generate photocurrent after receiving the side light beam LS of the light-emitting-diode die 120.

The disclosure does not intend to limit the number of electrically-connected substrates. In other embodiments, if one of the positive terminal and the negative terminal of the light-emitting-diode die 120 faces the substrate 110, only one electrically-connected substrate is provided between the light-emitting-diode die 120 and the substrate 110 to electrically connect the positive terminal or the negative terminal of the light-emitting-diode die 120. In some embodiments, when none of the positive terminal and the negative terminal of the light-emitting-diode die 120 faces the substrate 110, an insulation substrate can be disposed between the light-emitting-diode die 120 and the substrate 110 to raise the light-emitting-diode die 120.

FIG. 1C is another top view of another exemplary embodiment of the light-emitting device of the disclosure. In this embodiment, the light-emitting element 100C comprises light-emitting-diode dies 120A-120H and a photosensitive element 130. The light-emitting-diode dies 120A-120H and the photosensitive element 130 are disposed on the substrate 110. Each of the light-emitting-diode dies 120A-120H is disposed around the photosensitive element 130. In this embodiment, the light-emitting-diode dies 120A-120H surround the photosensitive element 130. Since there is no other element between the photosensitive element 130 and each of the light-emitting-diode dies 120A-120H, the side light beam emitted from each of the light-emitting-diode dies 120A-120H can directly enter the photosensitive element 130 without being blocked by other elements.

The wavelength of the light emitted by at least one of the light-emitting-diode dies 120A-120H may be the same as or different from the wavelength of the light emitted by the other one of the light-emitting-diode dies 120A-120H. In addition, the disclosure does not intend to limit the number of light-emitting-diode dies. In other embodiments, the light-emitting device 100C may comprise more or less light-emitting-diode dies. In addition, the disclosure does not intend to limit the number of photosensitive elements 130. In other embodiments, the light-emitting device 100C may comprise more photosensitive elements 130.

In some embodiments, the light-emitting device 100C further comprises terminals 170A-170L. The terminals 170A-170L are electrically connected to the light-emitting-diode dies 120A-120H and the positive terminal and the negative terminal of the photosensitive element 130. The disclosure does not intend to limit the number of terminals of the photosensitive element 130. In an exemplary embodiment, the number of terminals of the photosensitive element 130 is related to the positions of the positive terminals and the negative terminals of the light-emitting-diode dies 120A-120H and the photosensitive element 130.

Taking the light-emitting-diode die 120C as an example, if the positive terminal and the negative terminal of the light-emitting-diode die 120C face the substrate 110, the positive terminal and the negative terminal of the light-emitting chip 120C can be electrically connected to two terminals (such as the terminals 170A and 170B). If one of the positive terminal and the negative terminal of the light-emitting-diode die 120C faces the substrate 110, the other one of positive terminal and the negative terminal facing the substrate 110 can be electrically connected to one terminal (such as the terminal 170A).

FIG. 1D is a top view of another exemplary embodiment of a light-emitting device of the disclosure. The light-emitting element 100D comprises light-emitting-diode dies 120I-120K and a photosensitive element 130. The light-emitting-diode die 120I is disposed between the light-emitting-diode dies 120J and 120K and the photosensitive element 130. In this embodiment, the light-emitting device 100D further comprises terminals PD−, PD+, LD1−, LD1+, LD2−, LD2+, LD3−, and LD3+.

It is assumed that the negative terminal of the photosensitive element 130 faces the substrate 110, and the positive terminal of the photosensitive element 130 faces away from the substrate 110. In this example, the negative terminal of the photosensitive element 130 is electrically connected to the substrate 110 through a conductive material. At this time, the substrate 110 is implemented by a conductive substrate. The negative terminal of the photosensitive element 130 is electrically connected to the outside through the substrate 110 and the terminal PD−. In addition, the positive terminal of the photosensitive element 130 is electrically connected to the terminal PD+ through a conductive line 160A.

In an exemplary embodiment, the positive terminal and the negative terminal of the light-emitting-diode die 120I face the substrate 110. In this embodiment, the positive terminal of the light-emitting-diode die 120I is electrically connected to an electrically-connected substrate 140C, and the negative terminal of the light-emitting-diode die 120I is electrically connected to an electrically-connected substrate 140D. The substrate 110 is electrically insulated from the electrically-connected substrates 140C and 140D, that is, there is non-conduction between the electrically-connected substrates 140C and 140D and the substrate 110. The electrically-connected substrate 140C is electrically connected to the terminal LD1− through a conductive wire 160B. The electrically-connected substrate 140D is electrically connected to the terminal LD1+ through a conductive wire 160G.

In another exemplary embodiment, the positive terminal of the light-emitting-diode die 120J faces the substrate 110, and the negative terminal of the light-emitting-diode die 120J faces away from the substrate 110. In this embodiment, the positive terminal of the light-emitting-diode die 120I is electrically connected to the electrically-connected substrate 140E. The substrate 110 is electrically insulated from the electrically-connected substrate 140E, that is, there is non-conduction between the electrically-connected substrate 140E and the substrate 110. The electrically-connected substrate 140E is electrically connected to the terminal LD2+ through a conductive wire 160F. The negative terminal of the light-emitting-diode die 120J is electrically connected to the terminal LD2− through a conductive wire 160E.

In an exemplary embodiment, the positive terminal and the negative terminal of the light-emitting-diode die 120K face the substrate 110. In this embodiment, the positive terminal of the light-emitting-diode die 120K is electrically connected to the electrically-connected substrate 140F, and the negative terminal of the light-emitting-diode die 120K is electrically connected to the electrically-connected substrate 140G. The substrate 110 is electrically insulated from the electrically-connected substrates 140F and 140G, that is, there is non-conduction between the electrically-connected substrates 140F and 140G and the substrate 110. The electrically-connected substrate 140F is electrically connected to the terminal LD3+ through a conductive wire 160C. The electrically-connected substrate 140G is electrically connected to the terminal LD3− through a conductive wire 160D.

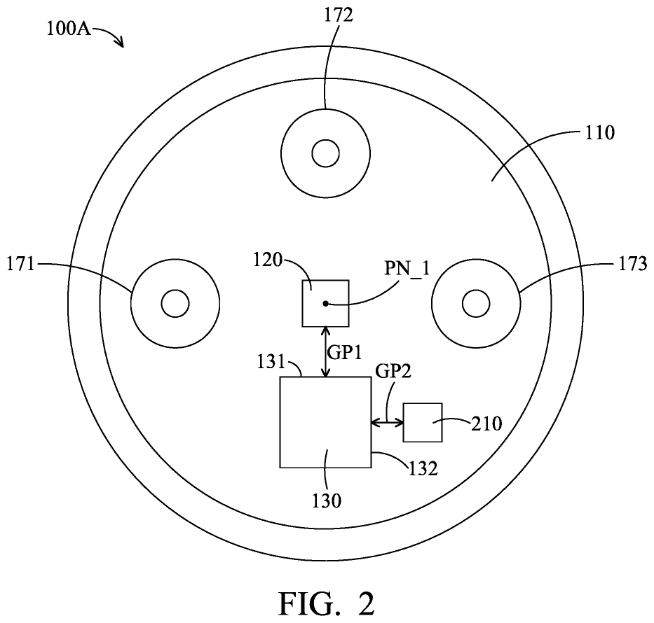

FIG. 2 is a schematic diagram showing an exemplary embodiment of the positions of the light-emitting-diode die 120 and the photosensitive element 130 of the disclosure. The light-emitting-diode die 120 is adjacent to the side surface (the photosensitive surface) 131 of the photosensitive element 130. There is a gap GP1 between the light-emitting-diode die 120 and the photosensitive element 130. In an exemplary embodiment, the gap GP1 is about 300 μm. In this embodiment, the distance between the light-emitting-diode die 120 and the central point PN_1 of the substrate 110 is smaller than the distance between the photosensitive element 130 and the central point PN_1. The disclosure does not intend to limit the shape of the substrate 110. In an exemplary embodiment, the shape of the substrate 110 is circular.

In some embodiments, the light-emitting device 100A further comprises another light-emitting-diode die 210. The light-emitting-diode die 210 is adjacent to a side surface 132 of the photosensitive element 130. There is a gap GP2 between the light-emitting-diode die 210 and the photosensitive element 130. The side light beam emitted by the light-emitting-diode die 210 enters the photosensitive element 130 directly through the gap GP2. In an exemplary embodiment, the wavelength of the light emitted by the light-emitting-diode die 120 may be the same as or different from the wavelength of the light emitted by the light-emitting-diode die 210. In some embodiments, the light-emitting-diode die 210 is used to correct the degradation of the photosensitive element 130.

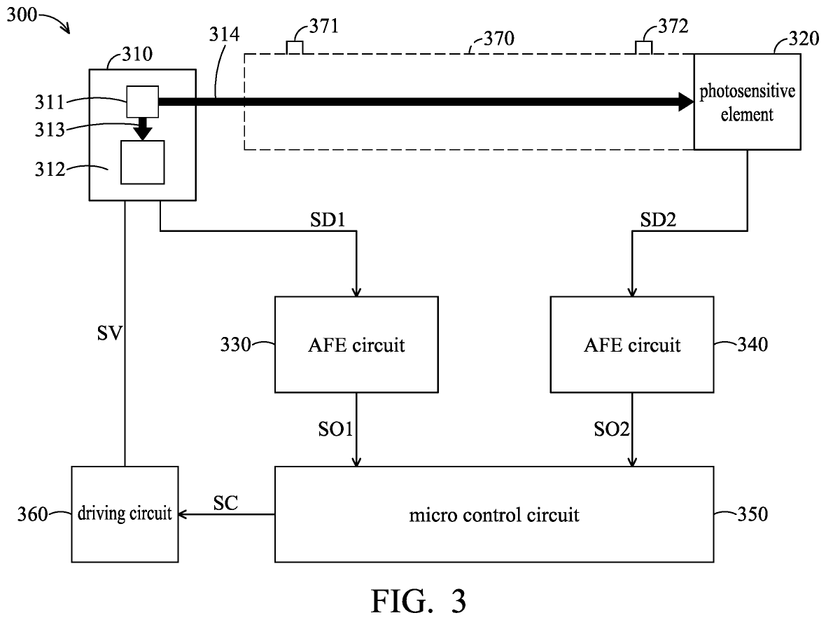

FIG. 3 is a schematic diagram showing an exemplary embodiment of a sensing device of the disclosure. The sensing device 300 comprises a light-emitting device 310, a photosensitive element 320, an analog front-end (AFE) circuits 330 and 340, a micro control circuit 350, a driving circuit 360, and a sensing cavity 370. The light-emitting device 310 emits a main light beam 314 and comprises a light-emitting-diode die 311 and a photosensitive element 312. The disclosure does not intend to limit the number of light-emitting-diode dies. In other embodiments, the light-emitting device 310 comprises more light-emitting-diode dies. In an exemplary embodiment, the light-emitting device 100A in FIG. 1A can be used as the light-emitting device 310.

In the embodiment, the light-emitting-diode die 311 emits the main light beam 314 and a side light beam 313 according to a driving signal SV. The photosensitive element 312 senses the optical power of the side light beam 313 to generate a detection result SD1. Since the characteristics of the light-emitting-diode die 311 and the photosensitive element 312 are similar to those of the light-emitting-diode die 120 and the photosensitive element 130, details are not repeated here.

The sensing cavity 370 is disposed between the light-emitting device 310 and the photosensitive element 320. The main light beam 314 emitted from the main light-emitting top surface of the light-emitting-diode die 311 passes through the sensing cavity 370. In an exemplary embodiment, the sensing cavity 370 comprises an injection hole 371 and an output hole 372. A substance to be detected enters the sensing cavity 370 through the injection hole 371 and flows out of the sensing cavity 370 through the output hole 372. The disclosure does not intend to limit the type of the substance to be detected. In an exemplary embodiment, the substance to be detected is a gas to be detected or a liquid to be detected. In some embodiments, when the sensing cavity 370 is filled with the substance to be detected, the concentration of the substance to be detected can be detected through the Beer-Lambert Law. In other embodiments, the sensing cavity 370 may be omitted, and the main light beam 314 emitted by the light-emitting-diode die 311 passes through the gas or liquid to be detected and then reaches the photosensitive element 320.

The photosensitive element 320 senses the brightness of the main light beam 314 passing through the sensing cavity 370 to generate a detection result SD2. In other embodiments, when the light-emitting device 310 comprises more light-emitting-diode dies, the photosensitive element 320 detects the brightness of the different light-emitting-diode dies at different time points.

The analog front-end circuit 330 processes the detection result SD1 to generate an output signal SO1. In an exemplary embodiment, the analog front-end circuit 330 amplifies the detection result SD1 and takes the amplified result as an output signal SO1. The analog front-end circuit 340 processes the detection result SD2 to generate an output signal SO2. In an exemplary embodiment, the analog front-end circuit 340 amplifies the detection result SD2 and takes the amplified result as an output signal SO2.

The micro control circuit 350 receives the output signals SO1 and SO2 and generates a control signal SC according to the output signals SO1 and SO2. In an exemplary embodiment, the control signal SC is a pulse width modulation (PWM) signal. The micro control circuit 350 processes the output signals SO1 and SO2 and estimates the concentration of a specific substance (for example, ozone (O3), nitrogen oxides (NOx), ammonia (NH3), chemical oxygen demand (COD), or suspended particles (SS)) in the sensing cavity 370 through the Beer-Lambert law. In other embodiments, when the light-emitting device 310 comprises more light-emitting-diode dies, the micro control circuit 350 can obtain the concentrations of more types of substances. In an exemplary embodiment, the micro control circuit 350 is a micro control unit (MCU).

The driving circuit 360 controls the luminous intensity of the light-emitting-diode die 311 according to the control signal SC. In an exemplary embodiment, the driving circuit 360 generates a driving signal SV according to the control signal SC to adjust the intensity of the main light beam 314 and the side light beam 313 emitted by the light-emitting-diode die 311. For example, when the brightness of the light-emitting-diode die 311 is less than a preset value, the micro control circuit 350 instructs the driving circuit 360 to increase the brightness of the light-emitting-diode die 310. When the brightness of the light-emitting-diode die 311 is greater than a preset value, the micro control circuit 350 instructs the driving circuit 360 to reduce the brightness of the light-emitting-diode die 310. In an exemplary embodiment, the driving signal SV is a current signal. In other embodiments, the driving circuit 360 may be integrated in the micro control circuit 350.

In some embodiments, the sensing cavity 370 may be omitted. In these embodiments, the sensing device 300 is directly placed in a space to be detected. The micro control circuit 350 estimates the concentration of a specific substance in the space to be detected according to the output signals SO1 and SO2. For example, multiple sensing devices 300 may be placed in an outdoor space to monitor the amount of ozone in different locations. In this example, the multiple sensing devices 300 form a smart air quality monitoring network and upload the monitored results to the same cloud. Users can know the air quality of the outdoor space through the information presented on the cloud.

The disclosure does not intend to limit the application field of the sensing device 300. The sensing device 300 can be applied to any field requiring a stable light source. For example, the sensing device 300 can be used as an optical sensor for sensing a specific component in the gas or water. In addition, the sensing device 300 can also be applied in the field of agriculture or biomedicine. The sensing device 300 can also be applied in an LED display to control the chromaticity color shift of the display and the brightness of pixels.

In the embodiment, since the photosensitive element 312 is embedded in the light-emitting device 310, the circuit of the sensing device 300 can be simplified, and the cost of the elements can be reduced. Moreover, since the light-emitting device 310 has a self-sensing function, the micro control circuit 350 obtains the optical power of the light-emitting device 310 according to the output signal SO1 and properly adjusts the optical power of the light-emitting device 310 through the control signal SC so that the light-emitting device 310 provides stable brightness. Meanwhile, the distance, relative position and the environment between the light-emitting-diode die and the photosensitive element 312 could be precisely known, so the brightness of the light-emitting device 310 can be controlled precisely. Therefore, the sensing accuracy and brightness stability can be improved.

In some embodiments, when the light-emitting device 310 comprises multiple light-emitting-diode dies, the sensing device 300 can detect various characteristic components. For example, when the first light-emitting-diode die in the light-emitting device 310 is lit, the micro control circuit 350 obtains the concentration of a first specific component (such as ozone) in a substance to be detected according to the output signals SO1 and SO2. In this example, when the second light-emitting-diode die in the light-emitting device 310 is lit, the micro control circuit 350 obtains the concentration of a second specific component (such as carbon dioxide) in a substance to be detected according to the output signals SO1 and SO2.

In some embodiments, the micro control circuit 350 monitors the output signal SO1 for adjusting the brightness of the light-emitting-diode die 311. In an exemplary embodiment, even if the driving signal SV is not changed, the optical power of the light-emitting-diode die 310 may drift so that the brightness of the light-emitting-diode die 310 cannot be kept stable. However, the micro control circuit 350 obtains the drifting state of the optical power of the light-emitting-diode die 310 according to the output signals SO1 and SO2, and compensates for the brightness fluctuation of the light-emitting-diode die 310 through the control signal SC. Therefore, the sensing accuracy of the photosensitive element 320 can be improved.

In addition, the micro control circuit 350 obtains the remaining lifetime of the light-emitting-diode die 311 according to the output signal SO1. For example, due to the physical phenomenon related to the luminous decay of the light-emitting-diode die 311, the luminous intensity of the light-emitting-diode die 311 will decrease with time, which causes the sensed optical power of the photosensitive elements 312 and 320 to decrease with time. Therefore, the micro control circuit 350 detects the optical power of the light-emitting-diode die 311 during a first fixed period to determine whether it is necessary to notify the user to replace the light-emitting-diode die 311.

The disclosure does not intend to limit how the micro control circuit 350 determines the aging state of the light-emitting-diode die 311. In an exemplary embodiment, during an initialization period, the micro control circuit 350 instructs the driving circuit 360 through the control signal SC to generate and transmit a preset driving current (Ii) to the light-emitting-diode die 311. The micro control circuit 350 calculates an initial optical power (Ui) of the light-emitting-diode die 311 according to the output signal SO1. The micro control circuit 350 records the initial optical power (Ui) of the light-emitting-diode die 311. Then, during an operation period, the micro control circuit 350 generates the control signal SC according to actual requirements. During the operation period, the micro control circuit 350 enters a first detection mode every fixed period (for example, 10 days). In the first detection mode, the micro control circuit 350 detects the aging degree of the light-emitting-diode die 311. After the detection is completed, the micro control circuit 350 leaves the first detection mode and generates the control signal SC again according to actual requirements.

In the first detection mode, the micro control circuit 350 may instruct the driving circuit 360 through the control signal SC to generate and output the preset driving current (Ii) to the light-emitting-diode die 311. The micro control circuit 350 calculates used optical power (Uo) according to the output signal SO1. In this example, the micro control circuit 350 calculates the initial optical power (Ui) and the used optical power (Uo) to obtain the aging degree of the light-emitting-diode die 311. The disclosure does not intend to limit how the micro control circuit 350 calculates the initial optical power (Ui) and the used optical power (Uo). In an exemplary embodiment, the micro control circuit 350 calculates the difference between the preset initial optical power (Ui) and the used optical power (Uo) and evaluates the aging degree of the light-emitting-diode die 311 according to the difference.

In another exemplary embodiment, in the first detection mode, the micro control circuit 350 instructs the driving circuit 360 through the control signal SC to generate and transmit a detection current (Jo) to the light-emitting-diode die 311 so that the optical power of the light-emitting-diode die 311 is the same as the initial optical power (Ui). In an exemplary embodiment, the micro control circuit 350 instructs the driving circuit 360 to generate and transmit a detection current (Jo) according to the initial optical power (Ui) and the used optical power (Uo). For example, the micro control circuit 350 instructs the driving circuit 360 to provide a test current to the light-emitting-diode die 311 first. In an exemplary embodiment, the test current is equal to the preset driving current (Ii). In this embodiment, since the light-emitting-diode die 311 is aged, the optical power of the light-emitting-diode die 311 is not equal to the initial optical power (Ui). The micro control circuit 350 calculates a correction current value according to the optical power of the light-emitting-diode die 311 and the initial optical power (Ui). The micro control circuit 350 instructs the driving circuit 360 to generate and transmit the detection current (Jo) according to the correction current value. At this time, the optical power of the light-emitting-diode die 311 is equal to the initial optical power (Ui). The micro control circuit 350 calculates the aging degree of the light-emitting-diode die 311 according to the preset driving current (Ii) and the detection current (Jo). The disclosure does not intend to limit how the micro control circuit 350 calculates the preset driving current (Ii) and the detection current (Io). In an exemplary embodiment, the micro control circuit 350 calculates the difference between the preset driving current (Ii) and the detection current (Jo) and evaluates the aging degree of the light-emitting-diode die 311 according to the calculation result.

In some embodiments, the micro control circuit 350 estimates the remaining lifetime of the light-emitting-diode die 311 according to the aging degree of the light-emitting-diode die 311. The micro control circuit 350 may upload the aging degree of the light-emitting-diode die 311 to a cloud. The user determines whether the light-emitting device 310 is replaced according to the data stored on the cloud. In another exemplary embodiment, when the aging degree of the light-emitting-diode die 311 reaches a threshold value, the micro control circuit 350 sends a warning message (not shown). According to the warning message sent by the micro control circuit 350, the user replaces the light-emitting device 310 in real time, so as to prevent the photosensitive element 320 from generating wrong sensing results.

In other embodiments, the micro control circuit 350 detects the degree of the contamination of the sensing cavity 370 according to the output signals SO1 and SO2. For example, during an initialization period, a reference substance or reference gas is filled into the sensing cavity 370. In an exemplary embodiment, the reference gas is zero air. During the initialization period, the micro control circuit 350 instructs the driving circuit 360 through the control signal SC to generate and transmit a preset driving current (Ii) to the light-emitting-diode die 311. The micro control circuit 350 calculates an initial optical power (Ui_1) of the light-emitting-diode die 311 according to the output signal SO1 and calculates an initial optical power (Ui_2) of the photosensitive element 320 according to the output signal SO2. The micro control circuit 350 records the initial ratio (Ri) between the initial optical power (Ui_1) of the light-emitting-diode die 311 and the initial optical power (Ui_2) of the photosensitive element 320.

During an operation period, a substance to be detected is filled into the sensing cavity 370. The micro control circuit 350 obtains the concentration of a specific component of the substance to be detected according to the output signals SO1 and SO2. In an exemplary embodiment, the micro control circuit 350 uploads the concentration of the specific component to the cloud. In this embodiment, the reference gas does not include this specific composition. For example, if the specific composition is ozone, the reference gas that is filled into the sensing cavity 370 during the initialization period does not include ozone.

During the operation period, the micro control circuit 350 enters a first detection mode every fixed period. In the first detection mode, the sensing cavity 370 is refilled with a reference material. The micro control circuit 350 requests the driving circuit 360 through the control signal SC to provide a test current (which may be the same as the preset driving current (Ii)) to the light-emitting-diode die 311. The micro control circuit 350 detects the optical power (which can be called as “the used optical power (Uo)”) of the light-emitting-diode die 311 according to the output signal SO1. The micro control circuit 350 generates a correction current value according to the difference between the used optical power (Uo) and the initial optical power (Ui_1). The micro control circuit 350 instructs the driving circuit 360 to generate and transmit a detection current (Jo) to the light-emitting-diode die 311 according to the correction current value. After the light-emitting-diode die 311 receives the detection current (Jo), the optical power of the light-emitting-diode die 311 is the same as the initial optical power (Ui_1). Then, the micro control circuit 350 obtains the optical power (Uo_1) of the photosensitive element 320 according to the output signal SO2. The micro control circuit 350 calculates the ratio (Ro) between the optical power of the light-emitting-diode die 311 (which is the same as the initial optical power (Ui_1)) and the optical power (Uo_1) of the photosensitive element 320. In this example, the micro control circuit 350 calculates the initial ratio (Ri) and the ratio (Ro) to obtain the degree of the contamination of the sensing cavity 370. The disclosure does not intend to limit how the micro control circuit 350 calculates the initial ratio (Ri) and the ratio (Ro). In an exemplary embodiment, the micro control circuit 350 calculates the difference between the initial ratio (Ri) and the ratio (Ro) and evaluates the degree of the contamination of the sensing cavity 370 according to the calculation result.

In some embodiments, the micro control circuit 350 uploads the degree of the contamination of the sensing cavity 370 to a cloud or presents it on a display. The user can immediately replace or clean the sensing cavity 370 to present the sensing accuracy of the image sensing device 300 from be affected disadvantageously.

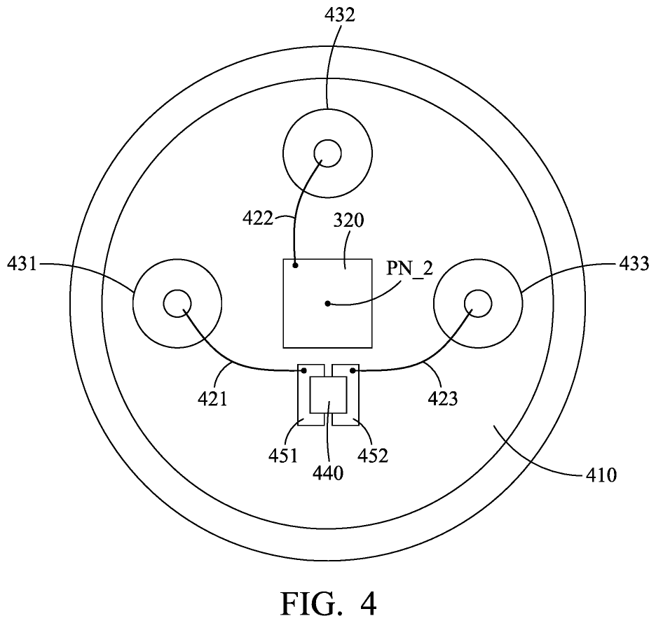

FIG. 4 is a schematic diagram showing an exemplary embodiment of the photosensitive element 320 of the disclosure. The photosensitive element 320 is disposed on a substrate 410. The disclosure does not intend to limit the shape of the substrate 410. In an exemplary embodiment, the shape of the substrate 410 is circular. The positive terminal of the photosensitive element 320 is electrically connected to a terminal 432 through a conductive wire 422. The negative terminal of the photosensitive element 320 is connected to the substrate 410 through a conductive material (such as conductive glue). In this embodiment, the substrate 410 is formed by a metal material (such as copper or iron, etc.). In this embodiment, the photosensitive element 320 covers the center point PN_2 of the substrate 410.

In some embodiments, the photosensitive element 320 is integrated with a light-emitting-diode die 440. In the embodiment, the light-emitting-diode die 440 and the photosensitive element 320 are disposed on the same substrate 410. The light-emitting-diode die 440 is adjacent to the photosensitive element 320. The distance between the photosensitive element 320 and the central point PN_2 is less than the distance between the light-emitting-diode die 440 and the central point PN_2.

In an exemplary embodiment, both the positive terminal and the negative terminal of the light-emitting-diode die 440 face the substrate 410. In this embodiment, electrically-connected substrates 451 and 452 are disposed between the light-emitting-diode die 440 and the substrate 410. The electrically-connected substrate 451 is electrically connected to the positive terminal of the light-emitting-diode die 440, and the electrically-connected substrate 452 is electrically connected to the negative terminal of the light-emitting-diode die 440. The substrate 110 is electrically insulated from the electrically-connected substrates 451 and 452, that is, there is non-conduction between the electrically-connected substrates 451 and 452 and the substrate 110. The electrically-connected substrate 451 is electrically connected to a terminal 431 through a conductive wire 421. The electrically-connected substrate 452 is electrically connected to a terminal 433 through a conductive wire 423. After an appropriate current is provided to the terminals 431 and 433, the light-emitting-diode die 440 can be driven.

In the embodiment, the light-emitting-diode die 440 is used to compensate for the luminous decay and the zero-point drifting of the photosensitive element 320. For example, the micro control circuit 350 enters a second detection mode every second fixed period. In the second detection mode, the micro control circuit 350 temporarily turns off the light-emitting device 310 through the control signal SC. The micro control circuit 350 provides a preset current to the light-emitting-diode die 440 so that the light-emitting chip 440 provides preset brightness. The micro control circuit 350 determines whether the optical power of the photosensitive element 320 has been decayed according to the output signal 502. In an exemplary embodiment, the micro control circuit 350 may compare the optical power of the photosensitive element 320 with a threshold value. The case where the optical power of the photosensitive element 320 is less than the threshold value indicates that the photosensitive element 320 has been decayed. In this embodiment, the micro control circuit 350 may upload a warning message to the cloud. Then, the micro control circuit 320 turns off the light-emitting-diode die 440, leaves the second detection mode, and then re-enables the light-emitting device 310. In this embodiment, the light-emitting-diode die 440 emits light when the micro control circuit 320 enters the second detection mode, and the light-emitting-diode die 440 stops emitting light when the micro control circuit 350 leaves the second detection mode.

In some embodiments, the duration of the first fixed period is different from the duration of the second fixed period. In other words, the micro control circuit 350 enters the first or second detection mode at different time points. In other embodiments, the micro control circuit 350 enters a correction mode every third fixed period. In the correction mode, the micro control circuit 350 obtains the optical power of the photosensitive element 320 according to the output signal SO2. When the optical power of the photosensitive element 320 is decayed, the micro control circuit 350 provides a correction current to the light-emitting-diode die 440 to instruct the light-emitting-diode die 440 to provide corrected brightness. In the embodiment, when the optical power of the photosensitive element 320 is decayed more, the correction current is greater, and thus the brightness of the light-emitting chip 440 is greater. In the embodiment, when the micro control circuit 350 enters the correction mode, the micro control circuit 350 adjusts the correction current. When the micro control circuit 320 leaves the correction mode, the light-emitting-diode die 440 continues to emit light according to the correction current.

In some embodiments, when the light-emitting-diode die 440 is integrated with the photosensitive element 320 of FIG. 3, the light-emitting-diode dies 311 and 440 may emit light at the same time. In the embodiment, the light-emitting-diode dies 311 and 440 may be driven by the same driving circuit 360. In an exemplary embodiment, the micro control circuit 350 provides different control signals to the driving circuit 360 so that the driving circuit 360 generates different driving signals.

It will be understood that when an element or layer is referred to as being “on”, “connected to” or “coupled to” another element or layer, it can be directly on, connected or coupled to the other element or layer or intervening elements or layers may be present. In contrast, when an element or layer is referred to as be “directly on”, “directly connected to” or “directly coupled to” another element or layer, there are no intervening elements or layers present.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein. It will be understood that although the terms “first,” “second,” etc. may be used herein to describe various elements, these elements should not be limited by these terms. These terms are only used to distinguish one element from another.

While the disclosure has been described by way of example and in terms of the preferred embodiments, it should be understood that the disclosure is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A light-emitting device with a sensing function, comprising:
a substrate;
a first light-emitting-diode die, disposed on the substrate, comprising a main light-emitting top surface and a side light-emitting surface surrounding the main light-emitting top surface; and
a first photosensitive element, disposed on the substrate, comprising a photosensitive surface, wherein the photosensitive surface is parallel to the main light-emitting top surface,
wherein a distance between the main light-emitting top surface and the substrate is greater than a distance between the photosensitive surface and the substrate distance.

2. The light-emitting device with a sensing function as claimed in claim 1, wherein a gap is located between the side light-emitting surface and the first photosensitive element, and light emitted from the side light-emitting surface directly passes through the gap and enters the photosensitive surface.

3. The light-emitting device with a sensing function as claimed in claim 1, further comprising:
a conductive substrate disposed between the first light-emitting-diode die and the substrate and electrically connected to the first light-emitting-diode die.

4. The light-emitting device with a sensing function as claimed in claim 1, wherein the substrate has a center point, and a distance between the first light-emitting-diode die and the center point is less than a distance between the first photosensitive element and the center point.

5. The light-emitting device with a sensing function as claimed in claim 4, further comprising:
a second light-emitting-diode die disposed on the substrate.

6. The light-emitting device with a sensing function as claimed in claim 5, wherein the first light-emitting-diode die is disposed between the second light-emitting-diode die and the first photosensitive element.

7. The light-emitting device with a sensing function as claimed in claim 1, wherein the substrate has a center point, and a distance between the first photosensitive element and the center point is less than a distance between the first light-emitting-diode die and the center point.

8. The light-emitting device with a sensing function as claimed in claim 1, further comprising:
a protection plate, surrounding the first light-emitting-diode die and the first photosensitive element, comprising a side surface,
wherein the side surface faces the first light-emitting-diode die and the first photosensitive element, and the side surface is coated with a light-absorbing material.

9. The light-emitting device with a sensing function as claimed in claim 8, further comprising:
a lens covering the first light-emitting-diode die and the first photosensitive element.

10. A sensing device comprising:
a light-emitting device comprising:
a substrate;
a light-emitting-diode die, disposed on the substrate, comprising a main light-emitting top surface and a side light-emitting surface, wherein the side light-emitting surface surrounds the main light-emitting top surface; and
a first photosensitive element, disposed on the substrate, comprising a photosensitive surface,
wherein the first photosensitive element receives an effective light through the photosensitive surface to generate a first detection result, and the photosensitive surface is parallel to the main light-emitting top surface, and
wherein a distance between the main light-emitting top surface and the substrate is greater than a distance between the photosensitive surface and the substrate,
a first analog front-end circuit, coupled to the light-emitting device to receive the first detection result, processing the first detection result to generate a first output signal;
a second photosensitive element sensing a light beam emitted by the light-emitting-diode die to generate a second detection result;
a second analog front-end circuit, coupled to the first photosensitive element to receive the second detection result, processing the second detection result to generate a second output signal;
a micro control circuit, coupled to the first analog front-end circuit and the second analog front-end circuit to receive the first output signal and the second output signal respectively, generating a control signal according to the first output signal and the second output signal; and
a driving circuit, coupled to the micro control circuit to receive the control signal, controlling luminous intensity of the light-emitting-diode die according to the control signal.

11. The sensing device as claimed in claim 10, wherein:
during an initialization period, the driving circuit generates and transmits a preset driving current to the light-emitting-diode die according to the control signal, and the micro control circuit calculates an initial optical power according to the first output signal,
during an operation period, the micro control circuit enters a detection mode every fixed period, and
in the detection mode, the micro control circuit detects an aging degree of the light-emitting-diode die according to the first output signal.

12. The sensing device as claimed in claim 11, wherein in the detection mode, the driving circuit outputs the preset driving current to the light-emitting-diode die, and the micro control circuit calculates used optical power according to the first output signal and further calculates the aging degree of the light-emitting-diode die according to the initial optical power and the used optical power.

13. The sensing device as claimed in claim 11, wherein in the detection mode, the micro control circuit calculates a correction current value according to the initial optical power and the used optical power and instructs the driving circuit to generate and transmit a detection current to the light-emitting-diode die according to the correction current value so that optical power of the light-emitting-diode die is the same as the initial optical power, and the micro control circuit calculates the aging degree of the light-emitting-diode die according to the preset driving current and the detection current.

14. The sensing device as claimed in claim 10, further comprising:
a sensing cavity, disposed between the light-emitting device and the second photosensitive element,
wherein light emitted from the main light-emitting top surface of the light-emitting-diode die passes through the sensing cavity.

15. The sensing device as claimed in claim 14, wherein:
during an initialization period, the sensing cavity is filled with a reference gas,
during an operation period, the sensing cavity is filled with a gas to be detected, and
during the operation period, the micro control circuit enters into a detection mode every fixed period to calculate the aging degree of the light-emitting-diode die.

16. The sensing device as claimed in claim 15, wherein during the operation period, the micro control circuit calculates concentration of a specific component in the gas to be detected, and the reference gas does not include the specific component.

17. The sensing device as claimed in claim 15, wherein:
during the initialization period, the driving circuit outputs a preset driving current to the light-emitting-diode die, and the micro control circuit calculates a first initial optical power according to the first output signal and calculates a second initial optical power according to the second output signal, and
in the detection mode during the operation period:
the micro control circuit instructs the driving circuit to output a test current to the light-emitting-diode die,
the micro control circuit calculates used optical power according to the first output signal, calculates a correction current value according to the first initial optical power and the used optical power, and instructs the driving circuit to generate and transmit a detection current to the light-emitting-diode die according to the correction current value so that optical power of the light-emitting-diode die is the same as the first initial optical power, and
the micro control circuit calculates an optical power of the second photosensitive element according to the second output signal and calculates the degree of contamination of the sensing cavity according to the first initial optical power and the optical power of the second photosensitive element.

18. The sensing device as claimed in claim 10, wherein the light-emitting device further comprises a gap, the gap is located between the side light-emitting surface and the first photosensitive element, and light emitted from the side light-emitting surface passes through the gap and enters the photosensitive surface.

19. The sensing device as claimed in claim 10, wherein the second photosensitive element is independent from the light-emitting device.

20. The sensing device as claimed in claim 10, wherein the substrate, the light-emitting-diode die, and the first photosensitive element are packaged together.
